(19) United States
(12) Patent Application Publication
(10) Pub. No.: US 2026/0118898 A1
(43) Pub. Date: Apr. 30, 2026

(54) POWER SUPPLY APPARATUS

(71) Applicant: DENSO CORPORATION, Kariya-city (JP)

(72) Inventor: Naoto YOKOYAMA, Kariya-city (JP)

(21) Appl. No.: 19/430,976

(22) Filed: Dec. 23, 2025

Related U.S. Application Data
(63) Continuation of application No. PCT/JP2024/020201, filed on Jun. 3, 2024.

(30) Foreign Application Priority Data
Jun. 29, 2023 (JP) 2023-107120

(51) Int. Cl. G05F 1/648; H02H 1/00; H02H 7/22

(52) U.S. Cl. CPC G05F 1/648; H02H 1/0007; H02H 7/228

(57) ABSTRACT

A power supply apparatus includes a power device, an I/V conversion circuit, a data converter, a controller, and sink-side current sources. The power device supplies current from a driving power supply to a load. The I/V conversion circuit detects a converted voltage generated by current passing through a detection resistor. The data converter converts the converted voltage into a data value based on a predetermined characteristic. The controller stops the power device from supplying the current to the load, on a condition that a calculated value derived from the data value exceeds a threshold value. The sink-side current sources, in multiple stages, superimpose an offset value on the current passing through the detection resistor.

### CROSS REFERENCE TO RELATED APPLICATIONS

The present application is a continuation application of International Patent Application No. PCT/JP2024/020201 filed on June 3, 2024, which designated the U.S. and claims the benefit of priority from Japanese Patent Application No. 2023-107120 filed on June 29, 2023. The entire disclosures of all of the above applications are incorporated herein by reference.

### TECHNICAL FIELD

The present disclosure relates to a power supply apparatus.

### BACKGROUND

A comparative power supply apparatus may execute a method for executing a fuse function using a semiconductor switch in order to protect a wire harness and a load. Such a protection function may be referred to as electronic Fuse (eFuse) control. In order to implement eFuse control, it may be necessary to cut off current in a short time during a high current condition due to a thermal time constant of the wire harness. On the other hand, to reduce cost by making the wire harness thinner, it may be necessary to improve the accuracy of current detection near the limit current that may be continuously supplied through the harness.

### SUMMARY

According to an aspect of the present disclosure, a power supply apparatus may include a power device, an I/V conversion circuit, a data converter, a controller and sink-side current sources. The power device may supply current from a driving power supply to a load. The I/V conversion circuit may convert the current into a voltage using a detection resistor through which the current passes. The data converter may convert the voltage into a data value based on a predetermined characteristic. The controller may execute a protection operation in which the power device is stopped from supplying the current to the load, on a condition that a calculated value derived from the data value exceeds a threshold value. The sink-side current sources may superimpose, in multiple stages, offset values of current on the current passing through the detection resistor.

### BRIEF DESCRIPTION OF DRAWINGS

Objects, features and advantages of the present disclosure will become more apparent from the following detailed description made with reference to the accompanying drawings. In the drawings:

FIG. 1 is a diagram showing the configuration of a power supply apparatus according to the first embodiment;

FIG. 2 is a diagram showing an offset current that is applied according to respective ON/OFF states of switches;

FIG. 3 is a diagram showing the relationship between a load current and an A/D conversion value in a case where the resistance value of an I/V conversion circuit is only a low resistance;

FIG. 4 is a diagram showing the relationship between the load current and the A/D conversion value in a case where the resistance value of the I/V conversion circuit can be switched between a low resistance and a high resistance;

FIG. 5 is a diagram showing the relationship between the load current and the A/D conversion value in the case where the resistance value of the I/V conversion circuit is switched and the value of the offset current is also switched;

FIG. 6 is a diagram showing the configuration of the power supply apparatus in the second embodiment;

FIG. 7 is a diagram showing the offset current supplied according to respective ON/OFF states of switches;

FIG. 8 is a diagram showing the configuration of the power supply apparatus in the third embodiment;

FIG. 9 is a diagram showing the relationship between the load current via the constant current circuit and the A/D conversion value;

FIG. 10 is a diagram showing the relationship between the load current and the A/D conversion value when the resistance value of the I/V conversion circuit is switched and the value of the offset current is also switched;

FIG. 11 is a flowchart showing the processing contents of the controller in the fourth embodiment;

FIG. 12 is a diagram showing the relationship between the load current and the A/D conversion value when the resistance value of the I/V conversion circuit is switched and the value of the offset current is also switched;

FIG. 13 is a diagram showing the configuration of the power supply apparatus in the fifth embodiment;

FIG. 14 is a diagram showing the relationship between the load current and the A/D conversion value when a positive offset current is superimposed on the sense MOS;

FIG. 15 is a diagram showing the relationship between the load current and the A/D conversion value when a negative offset current is superimposed on the sense MOS;

FIG. 16 is a diagram showing the relationship between the load current and the A/D conversion value when the resistance value of the I/V conversion circuit is switched and the value of the offset current is also switched;

FIG. 17 is a diagram (part 1) showing the configuration of the power supply apparatus in the sixth embodiment;

FIG. 18 is a diagram (part 2) showing the configuration of the same power supply apparatus;

FIG. 19 is a flowchart showing the processing contents of the controller;

FIG. 20 is a diagram (part 1) showing the configuration of the power supply apparatus in the seventh embodiment;

FIG. 21 is a flowchart showing the processing contents of the controller;

FIG. 22 is a diagram showing an example of a table used to identify the type of IPD;

FIG. 23 is a diagram (part 2) showing the configuration of the power supply apparatus;

FIG. 24 is a flowchart showing the processing contents of the controller in the eighth embodiment;

FIG. 25 is a diagram illustrating a process for correcting the A/D conversion result by applying a first-order function;

FIG. 26 is a diagram showing the configuration of the power supply apparatus in the ninth embodiment; and

FIG. 27 is a flowchart showing the processing contents of the controller.

### DETAILED DESCRIPTION

To improve current detection accuracy of a power supply apparatus, two types of resistors for I/V conversion may be provided for an output that may monitor current flowing through a semiconductor switch, and these resistors may be switched according to a current range. In this case, in the current region where it is necessary to switch from a high resistance to a low resistance for measurement, the measurement resolution of the current may decrease. Therefore, it may be required to activate a protection operation to cut off a circuit faster than an ideal fusing characteristics. In addition, for the high resistance side, it may be necessary to select a resistance value that ensures current detection accuracy near the level of current that can be continuously passed through the harness. Due to decreased measurement resolution and A/D conversion errors in a region where the load current is small, it may be difficult to determine the status of a load, such as load determination, wake-up/sleep, and other operating states. As a countermeasure, increasing the number of types of resistance values leads to a higher cost.

According to an aspect of the present disclosure, a power supply apparatus includes a power device, an I/V conversion circuit, a data converter, a protection operation unit, and sink-side current sources. The power device supplies current from a driving power supply to a load. The I/V conversion circuit converts the current into a voltage using a detection resistor through which the current passes. The data converter converts the voltage into a data value based on a predetermined characteristic. The protection operation unit executes a protection operation in which the power device is stopped from supplying the current to the load, on a condition that a calculated value derived from the data value exceeds a threshold value. The sink-side current sources superimpose, in multiple stages, offset values of current on the current passing through the detection resistor.

With such a configuration, by varying the offset value applied to the current supplied to the detection resistor using the sink-side current sources, it is possible to further reduce the voltage input to the data converter. As a result, it becomes possible to pseudo-improve the resolution of data conversion in the data converter.

Further, according to the power supply apparatus of the present disclosure, the sink-side current sources are set such that the voltage immediately before and immediately after a boundary between adjacent two of the offset values remain within an input range of the data converter. As a result, by applying the offset value, when the voltage converted by the I/V conversion circuit is in a low region and the output characteristics of the sink-side current source become non-linear, the offset value can be switched to a lower level; if the output characteristics of the sink-side current source are made linear, the overall output characteristics can be made linear throughout the entire range.

Further, according to the power supply apparatus of the present disclosure, a storage stores, in advance, a difference value among data values associated with on and off states of the sink-side current sources. A controller, upon switching of the sink-side current sources, reads from the storage the difference value corresponding to the switching, and subtract the difference value from the data value. As a result, the calculation process when switching the sink-side current source to be used is simplified.

Further, according to the power supply apparatus of the present disclosure, the I/V conversion circuit selectively supplies current to two or more detection resistors having different resistance values. The data converter executes a first data conversion in a state in which the current is supplied to a detection resistor having a lowest resistance value among the two or more detection resistors, without superimposing the offset value of current on the current. In accordance with a result of the first data conversion, the I/V conversion circuit selects a detection resistor having a higher resistance value than the detection resistor used in the first data conversion, and the data converter executes a second data conversion in which the current is supplied to the selected detection resistor. The controller determines, based on the result of the first data conversion, an offset value to be superimposed on the current for the second data conversion. As a result, current detection can be performed with high accuracy using at most two data conversions.

### First Embodiment

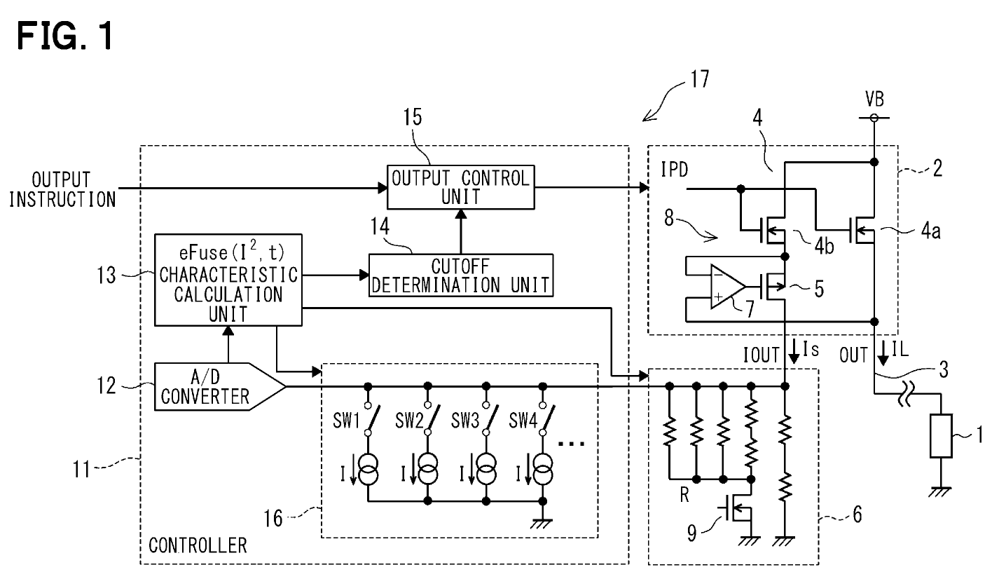

As shown in FIG. 1, a power supply apparatus according to the present embodiment supplies a current to a load 1 from a power supply VB via an intelligent power device (IPD) 2 and a harness 3. One end of the load 1 is connected to a ground. The IPD 2 includes N-channel MOSFETs 4a and 4b, whose drains are connected to the power supply VB and whose gates are commonly connected. The source of FET 4a, which is an example of a power device, is connected to the load 1 via the harness 3, and the source of FET 4b is connected to the ground via a P-channel MOSFET 5 and an I/V conversion circuit 6. In addition, the source of FET 4b, together with the source of FET 5, is connected to an inverting input terminal of an operational amplifier 7, while a non-inverting input terminal of the operational amplifier 7 is connected to the source of FET 4a. The FETs 4a and 4b form a transistor pair 4. FET 4b may also be referred to as a sense MOS. The FETs 4b and 5 and the operational amplifier 7 are included in a current output circuit 8.

The I/V conversion circuit 6 includes a combination of seven resistive elements, each serving as a detection resistor with a resistance value R, and a P-channel MOSFET 9. A first series connection of two resistive elements R is connected between the source of FET 4b and ground. A second series circuit of the two resistive elements R and the MOSFET 9 is connected in parallel to the first series connection. In addition, three resistive elements R are connected in parallel to the above-mentioned two resistive elements R. The gates of the transistor pair 4 and FET 9 are driven by the controller 11. The resistance value of the I/V conversion circuit 6 is 2R when FET 9 is off, and becomes R/4 when FET 9 is on. Hereinafter, the “2R” may be also referred to as “high resistance”; and the “R/4” may also be referred to as “low resistance.”

The controller described in the present disclosure may include a processor and a memory. The controller may execute the following functions (functional units) by executing a program stored in the memory through the processor. In additional, the controller may include a hardware logic circuit that executes the following functions. Moreover, the controller may execute the following functions with the combination of the processor and the hardware logic circuit.

Inside the controller 11, an A/D converter 12, an eFuse (I², t) characteristic calculation unit 13, a cutoff determination unit 14, and an output control unit 15 are connected in series. The input terminal of the A/D converter 12, which is an example of a data converter, is connected to the common connection node of the IPD 2 and the I/V conversion circuit 6. The data converted by the A/D converter 12 is provided to the eFuse (I², t) characteristic calculation unit 13 that may also be referred to as a calculation unit, a calculator, or a calculation circuit. The result calculated by the calculation unit 13 is provided to the cutoff determination unit 14, and the determination result of the cutoff determination unit 14 is provided to the output control unit 15. In the present disclosure, the calculation unit 13, the cutoff determination unit 14 and the output control unit 15 correspond to a protection controller.

The eFuse (I², t) characteristic calculation unit 13 is an example of a multiplication circuit or a multiplier that executes a calculation based on data proportional to the square of the detected current using the data converted by the A/D converter 12, and outputs the calculated result. This is based on the fact that the smoke generation time t of the harness 3 exhibits a characteristic dependent on the square of the current being supplied.

The cutoff determination unit 14 determines whether to provide a cutoff instruction by comparing the calculated data described above with a threshold value. The output control unit 15 drives the gates of the transistor pair 4 of the IPD 2 in accordance with an output instruction provided from a higher-level control device (not shown). In addition, when a cutoff instruction is provided from the cutoff determination unit 14, the output control unit 15, which corresponds to the protection operation unit, turns off the transistor pair 4.

A sink-side current source unit 16 is connected between the input terminal of the A/D converter 12 and ground. The sink-side current source unit 16 is provided with a series circuit in which a sink-side current source I is connected to each of switches SW1 to SW4. The on/off control of the FET 9 and switches SW1 to SW4 is performed by the calculation unit 13 for eFuse (I², t) characteristics. In the above, the parts other than the harness 3 and the load 1 are included in the power supply apparatus 17.

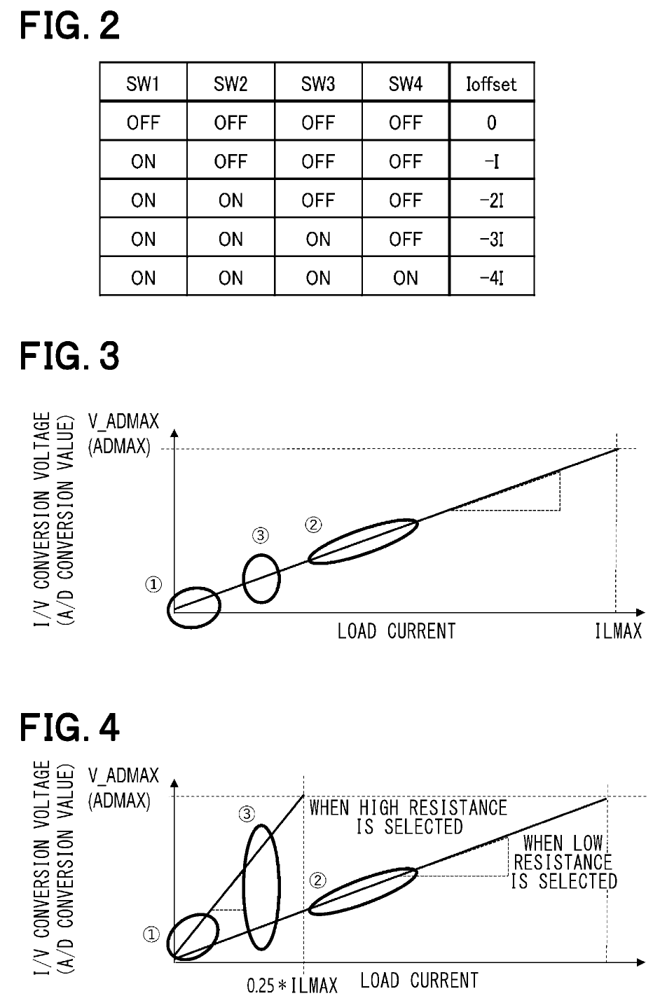

Next, the operation according to the present embodiment will be described. In the sink-side current source unit 16, the offset current flowing to the ground due to the operation of the current source I is defined as I_offset. The current I_offset reduces the current flowing to ground from the IPD 2 via the I/V conversion circuit 6. As shown in FIG. 2, by selectively turning on one of switches SW1 to SW4, the current I_offset varies in the range of -I to -4I.

As shown in FIG. 3, in the load current–I/V conversion characteristic when no I_offset current is supplied and the I/V conversion circuit 6 is in a low-resistance state, in the region (1) where the load current value is small, it becomes difficult to determine the acceptability of the load or to determine the wake-up/sleep state due to the influence of errors caused by A/D conversion. In addition, in region (2), because the current measurement resolution is low, it becomes necessary to operate the protection function so that IPD 2 is shut off earlier than the ideal fuse-blowing characteristic of harness 3. Region (3) indicates the current value that can be continuously supplied to harness 3. Note that the numbers in parentheses correspond to the circled numbers in the FIG. 3.

If the characteristics when the I/V conversion circuit 6 is in a high-resistance state are added to FIG. 3, the result is as shown in FIG. 4. In this way, even when switched to a high resistance, it is necessary to select a resistance value that ensures current detection accuracy in the vicinity of region (3).

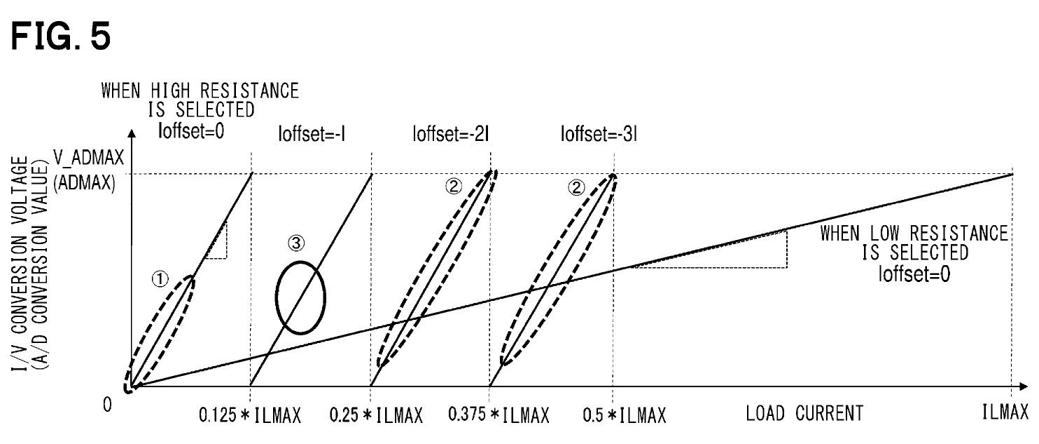

Then, when the current I_offset is varied as in the present embodiment, the load current–I/V conversion characteristics become as shown in FIG. 5. If the load current is IL, the monitoring current flowing to the I/V conversion circuit 6 side is IS, and the current ratio of the I/V conversion circuit 6 is KILIS, then the relationship between currents IL and IS is given by (IL = KILIS × IS). If the voltage generated across the I/V conversion circuit 6 denotes Vs, then when the I/V conversion circuit 6 is set to the high-resistance side, Vs = (IL/KILIS + I_offset) × 2R. When the I/V conversion circuit 6 is set to the low-resistance side, Vs = (IL/KILIS + offset) × R/4. If the upper limit detection current is defined as ILMAX, then Vs = (ILMAX/KILIS) × R/4 = V_ADMAX.

When no offset current Ioffset is applied, the load current IL isIL can only be detected within the range of 0 to 0.125/ILMAX. In contrast, in the present embodiment, the current I of the current source is set to (= V_ADMAX/2R), and with the I/V conversion circuit 6 selected to the high-resistance side, the offset current Ioffset is gradually increased in steps from 0 to -I, -2I, -3I, and so on.

When the current Ioffset is set to -I, the load current IL can be detected in the range of IL = 0.125 × ILMAX to 0.25 × ILMAX. If the current Ioffset is set to -2I or -3I, the range of 0.25 × ILMAX to 0.5 × ILMAX can be detected. If the current Ioffset is set to -4I, the range up to 0.75 × ILMAX can be detected. That is, whereas conventionally the range was IL = 0 to 0.25 × ILMAX with a resolution four times higher than during low-resistance switching, the method described in the present embodiment enables the current detection resolution to be increased eightfold across all regions (1) to (3), thereby reducing the influence of errors from the A/D converter 12.

As described above, according to the present embodiment, when supplying current to the load 1 from the drive power supply VB via the FET 4a and the harness 3, the I/V conversion circuit 6 converts the current, based on that supplied to the load, into a voltage by passing the current through a detection resistor. The A/D converter 12 converts the voltage, converted by the I/V conversion circuit 6, into a data value. The output control unit 15 performs a protection operation to stop the supply of current to the load 1 by the FET 4a when a calculated value based on the data value exceeds a threshold. Then, the sink-side current source unit 16 is configured so that an offset current Ioffset, corresponding to the current passing through the detection resistor, can be superimposed in multiple steps.

With this configuration, by varying the offset current Ioffset applied to the current passing through the detection resistor using multiple current sources I, the voltage provided to the A/D converter 12 can be further reduced. As a result, it becomes possible to pseudo-enhance the resolution of data conversion in the A/D converter 12.

### Second Embodiment

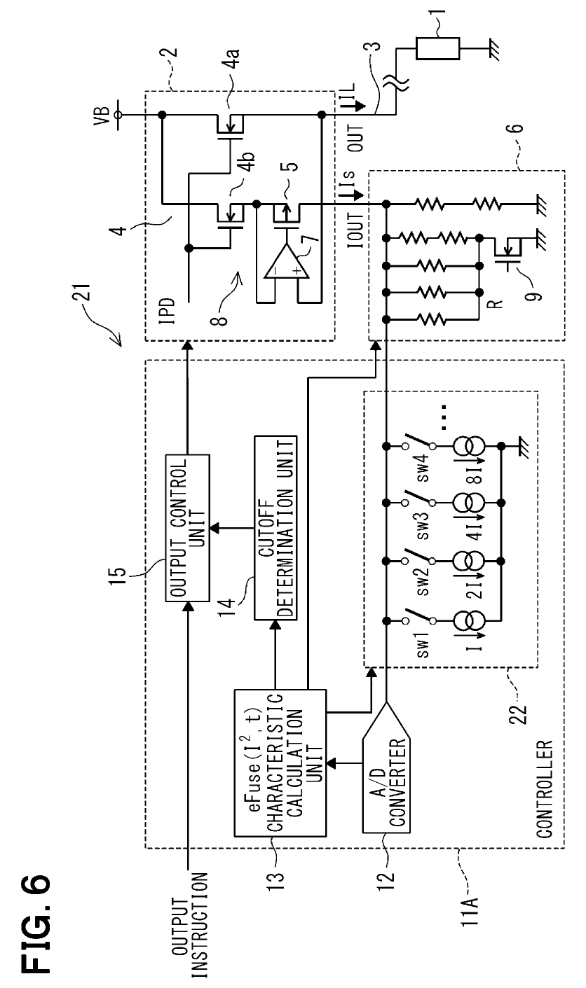

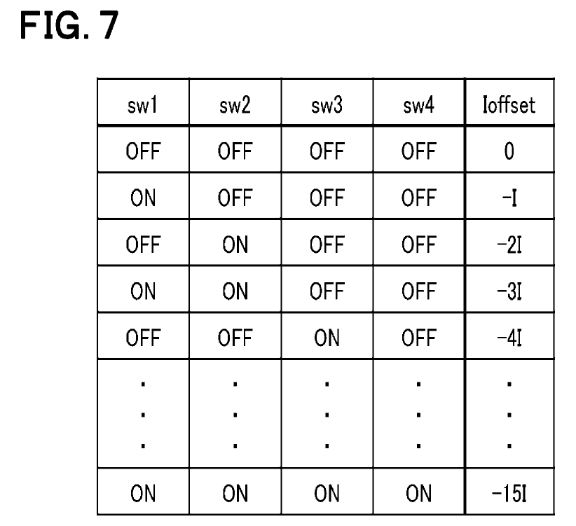

Hereinafter, parts identical to those in the first embodiment are denoted by the same reference numerals and their description will be omitted, while the different parts will be described. As shown in FIG. 6, the power supply apparatus 21 according to a second embodiment includes a sink-side current source unit 22 in place of the sink-side current source unit 16. In the sink-side current source unit 22, sink-side current sources I, 2I, 4I, and 8I are connected to respective switches SW1 through SW4. With this configuration, as shown in FIG. 7, by varying the on/off states of switches SW1 through SW4 in correspondence with 4-bit data so that the value ranges from “1 to 15,” the current I_offset can be varied accordingly within the range of “-I to -15I.”

### Third Embodiment

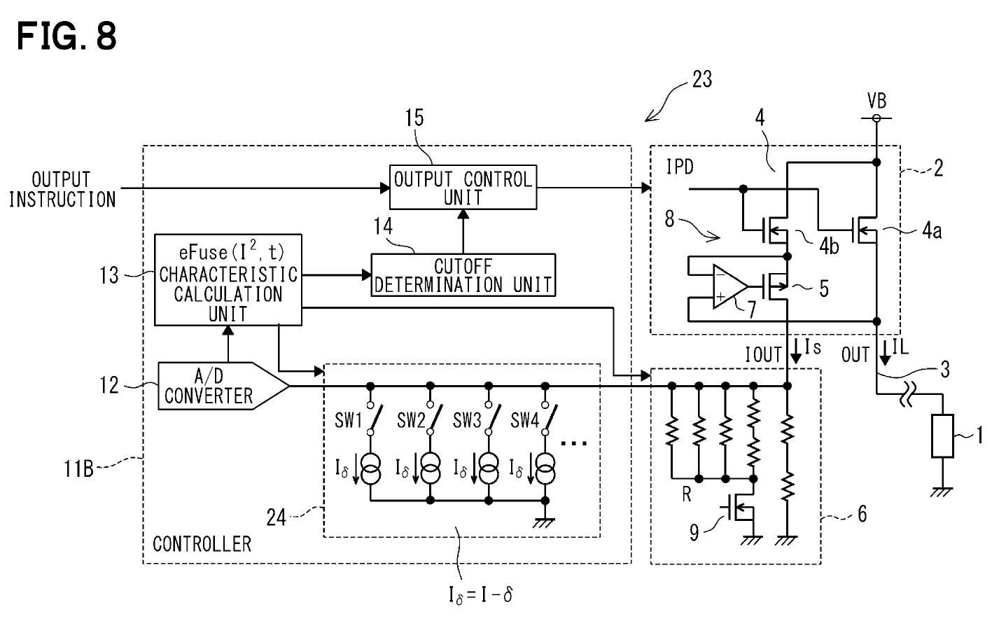

As shown in FIG. 8, a power supply apparatus 23 according to a third embodiment includes a sink-side current source unit 24 in place of the sink-side current source unit 16. The sink-side current source unit 24 includes four current sources Iδ, each having a constant current value of Iδ = (I - δ). Here, δ is defined as follows: when the voltage obtained by adding the on-resistance of FET 4b to the minimum resistance value of the I/V conversion circuit 6 and multiplying the resulting total resistance by the current flowing through them causes the potential of the ground to which the I/V conversion circuit 6 is connected to be shifted to a value higher than 0 V, and if this shifted voltage is denoted as V_diff, then δ is given by δ > (V_sat + V_diff) / (2R). The constant current value I is the same as in the first embodiment, that is, (= V_ADMAX / 2R).

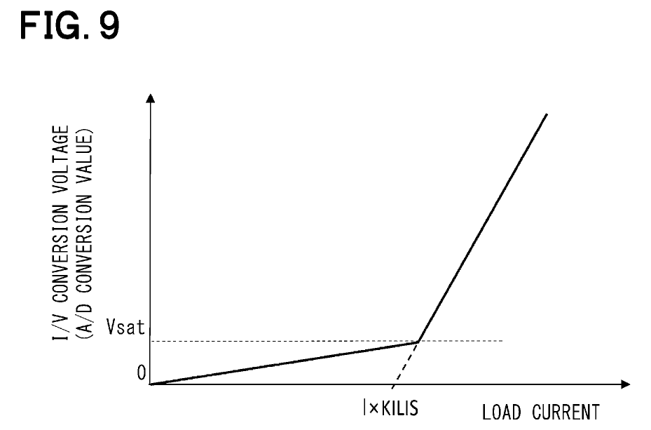

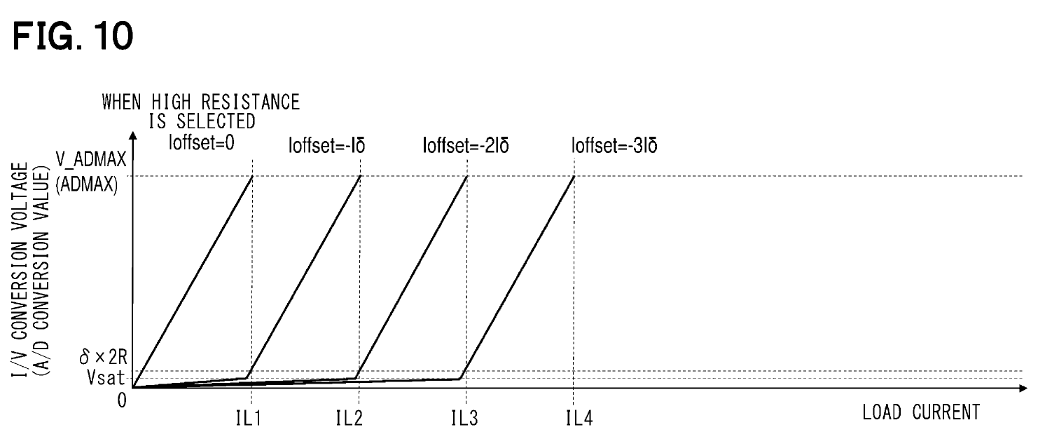

A constant current circuit such as the current output circuit 8 may not perform constant current operation in regions where the input voltage is low, as shown in FIG. 9, due to the on-resistance and saturation voltage of transistors as mentioned above, as well as voltages generated by resistances on the ground side. Therefore, by setting each current source Iδ of the sink-side current source unit 24 to (I − δ) and overlapping the range below the voltage V_sat, as shown in FIG. 10, it becomes possible to convert to a voltage in a region where all outputs are linear by switching the offset current I_offset to 0, −Iδ, −2Iδ, −3Iδ, and so on.

### Fourth Embodiment

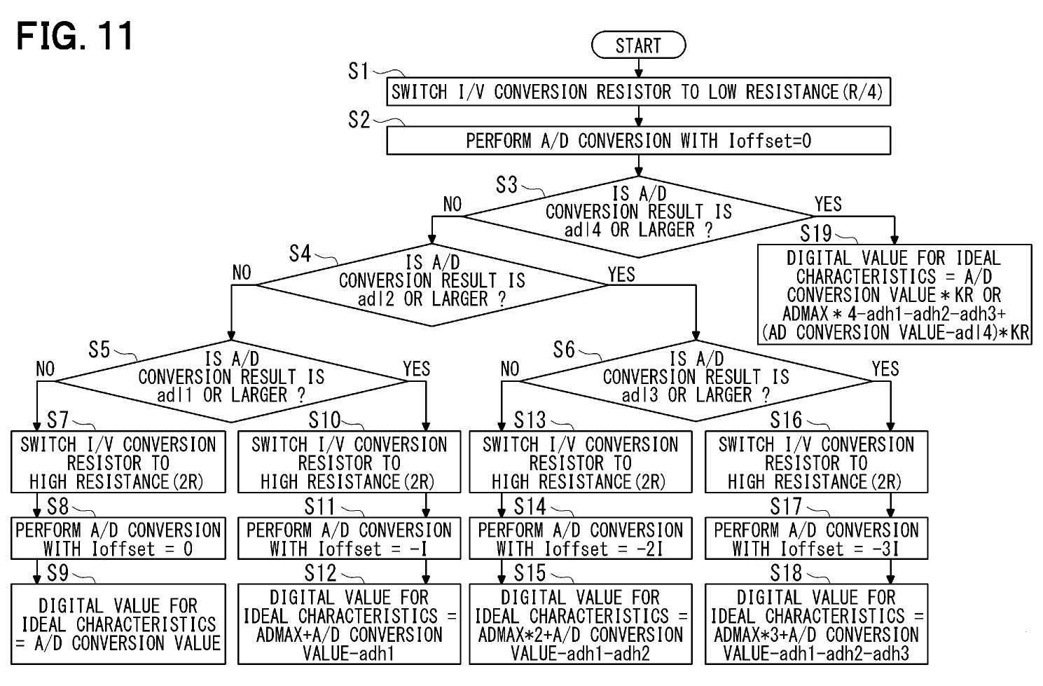

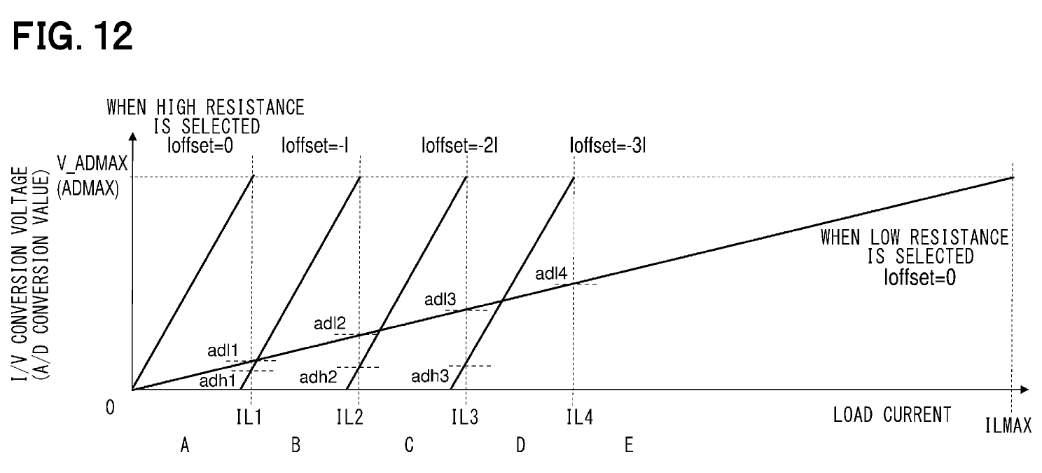

As shown in FIG. 11, the fourth embodiment illustrates the control contents in the controller 11. When processing starts, the resistance value of the I/V conversion circuit 6 is set to the lower value (R/4) in S1, and A/D conversion is performed with the current I_offset = 0 in S2. This corresponds to the first data conversion. Then, the result of the A/D conversion is compared with each of the conversion values adl4 to adl1, as shown in FIG. 12, to determine whether it is equal to or greater than each of the conversion values adl4 to adl1 in S3 to S6.

If the A/D conversion result is equal to or greater than the conversion value adl4 (S3: Yes), it belongs to the current region E (IL4 to ILMAX) shown in FIG. 12. Let KR be the ratio of the low resistance value to the high resistance value of the I/V conversion circuit 6. The final digital value corresponding to the detected current is obtained by multiplying the A/D conversion result by KR in S19. In the case of the fourth embodiment, KR = 8. It should be noted that the “ideal characteristic” shown in the drawing ignores the case where the conversion characteristic becomes nonlinear in the low current region, as in the third embodiment, for the sake of simplicity in explanation.

If the A/D conversion result is less than the conversion value adl1 (S5: No), it belongs to current region A (0 to IL1), and the resistance value of the I/V conversion circuit 6 is switched to the higher value of 2R in S7, after which A/D conversion in S8 is performed in the same way as in S2. Then, the A/D conversion result is directly used as the final digital value in S9. If the A/D conversion result is less than the conversion value adl2 and equal to or greater than the conversion value adl1 (S5: Yes), it belongs to current region B (IL1 to IL2), the same processing as in S7 is performed in S10, and A/D conversion is carried out with a current Ioffset = -I in S11. Then, by subtracting the conversion value adh1 (which corresponds to conversion value adl1 in the case of the high resistance value 2R) from the A/D conversion result, and adding the result to the maximum conversion value ADMAX, a digital value continuous with current region A is obtained in S12.

If the A/D conversion result is equal to or greater than the conversion value adl2 and less than the conversion value adl3 (S6: No), it belongs to current region C (IL2 to IL3), the same processing as in S7 is performed in S13, and A/D conversion is carried out with a current Ioffset = -2I in S14. Then, by subtracting the conversion value adh1 and the conversion value adh2 (which corresponds to the conversion value adl2 in the case of the high resistance value 2R) from the A/D conversion result, and adding the result to twice the maximum conversion value ADMAX, a digital value continuous with current region B is obtained in S15.

If the A/D conversion result is less than the conversion value adl4 and equal to or greater than the conversion value adl3 (S6: Yes), it belongs to current region D (IL3 to IL4), the same processing as in S7 is performed in S16, and A/D conversion is carried out with a current Ioffset = -3I in S17. Then, by subtracting the conversion values adh1 and adh2, as well as adh3 (which corresponds to the conversion value adl3 in the case of the high resistance value 2R), from the A/D conversion result, and adding the result to three times the maximum conversion value ADMAX, a digital value continuous with current region C is obtained in S15. S8, S11, S14, and S17 correspond to the second data conversion.

The digital value in S19, which is the result of the A/D conversion at low resistance multiplied by KR, is equal to the value obtained by subtracting conversion values adh1 to adh3 from four times the maximum conversion value ADMAX, and further adding the value obtained by multiplying by KR the difference between the A/D conversion result at low resistance and the conversion value adl1. In addition, the conversion values adh1 to adh3 represent the differences in A/D conversion values that occur when transitioning between current regions A to C by switching the current Ioffset using the sink-side current source unit 16. These values are stored in advance in a memory unit 11M (not shown) provided in the controller 11.

As described above, according to the fourth embodiment, the A/D conversion values adl1 to adl4 obtained when the I/V conversion circuit 6 is set to a low resistance value are stored in advance, and by comparing the actual A/D conversion result with these values, the current regions A to E are classified. For current regions A to D, the I/V conversion circuit 6 is switched to a high resistance value and A/D conversion is performed again. In addition, the conversion values adh1 to adh3 corresponding to the A/D conversion values adl1 to adl3 obtained when the I/V conversion circuit 6 is set to a low resistance value are also stored in advance. The final digital value is obtained by, for example, subtracting the conversion values adh1 to adh3 from the results of the subsequent A/D conversion. As a result, the conversion resolution in current regions A to D can be pseudo-increased with a maximum of two A/D conversions. Here, exception handling is omitted in S11 and S17, but if the input voltage exceeds the upper limit of the input voltage range of the A/D converter 12, it is also possible to obtain the digital value using the method of S19.

### Fifth Embodiment

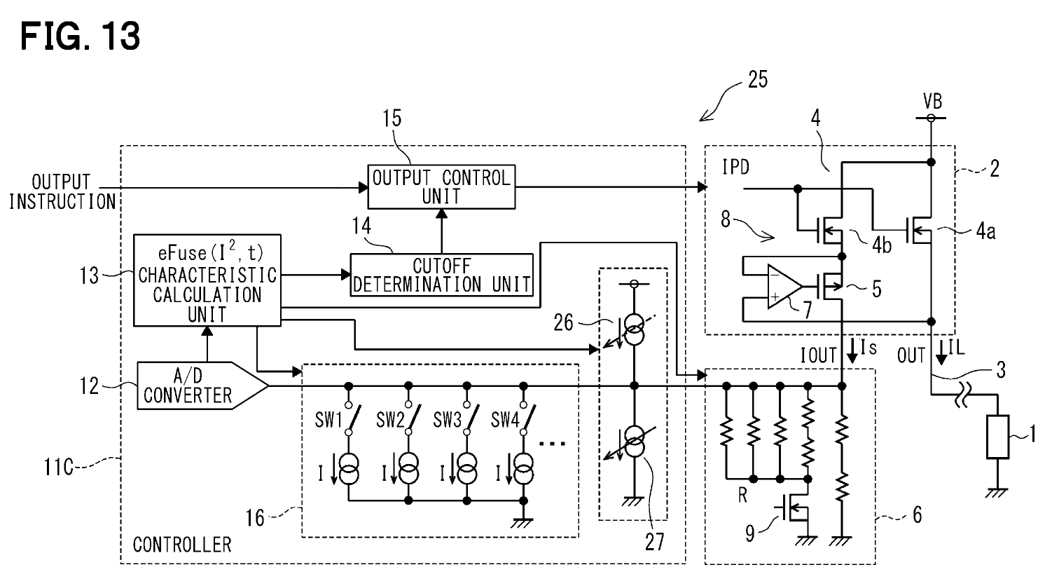

As shown in FIG. 13, a power supply apparatus 25 according to a fifth embodiment is provided with a source-side current source 26 and a sink-side current source 27 as correction current supply sources in the controller 11C. The source-side current source 26 is connected between the power supply VB and the input terminal of the A/D converter 12, and the sink-side current source 27 is connected between the above-mentioned input terminal and ground. Both current sources 26 and 27 are provided such that their constant current values are variable. This variable control is performed by the calculation unit 13 for the eFuse (I², t) characteristics.

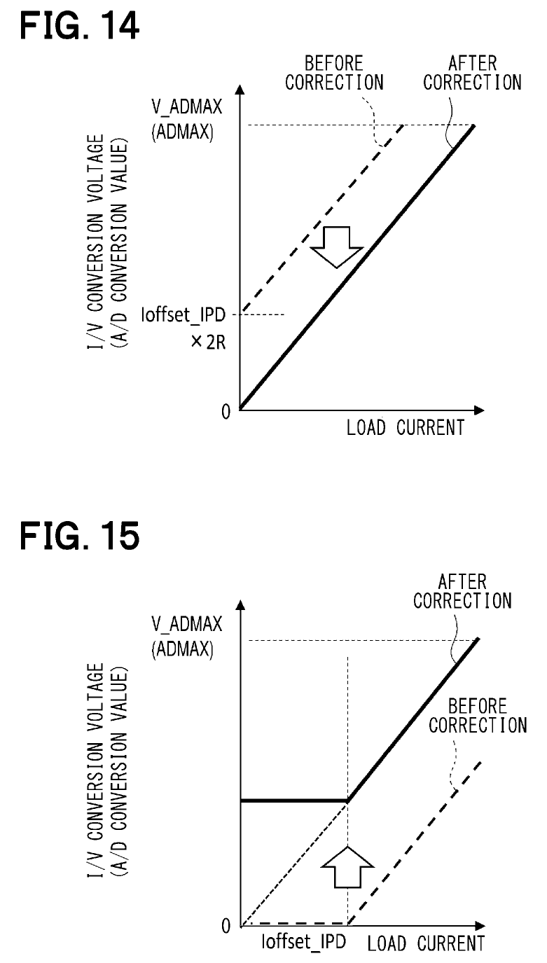

In IPD 2, when a positive offset current I_offset_IPD is superimposed on FET 4b, which is the sense MOS, the relationship between the load current IL and the monitor current output IS is “IL = KILIS × IS + I_offset_IPD”. This is the resulting relationship. Therefore, as shown by the dashed line in FIG. 14, when the resistance value of the I/V conversion circuit 6 is high (2R), an offset voltage (I_offset_IPD × 2R) is generated when the load current IL = 0 A, resulting in a reduced dynamic range.

In contrast, by adjusting the sink current I_offset_trim of the sink-side current source 27, whose constant current value is adjustable, to be approximately equal to “-I_offset_IPD” and supplying this current, the offset voltage can be reduced, thereby expanding the dynamic range.

Additionally, if a negative offset current I_offset_IPD is superimposed on FET4b, the relationship between the load current IL and the monitor current output IS is “IL = K_ILIS × IS − I_offset_IPD”. Therefore, as indicated by the dashed line in FIG. 15, in the range where the load current IL is from 0 A to I_offset_IPD, the A/D conversion value becomes nearly zero, and even in regions where the load current IL exceeds this range, the A/D conversion value is lower than its original value. As a result, the protection intended to prevent burnout of the harness 3 due to overcurrent becomes less effective. Therefore, by adjusting the source-side current source 26, which allows the constant current value to be set, to supply a source current I_offset_trim (approximately equal to -I_offset_IPD), the protection function for harness 3 can be maintained without reducing its effectiveness.

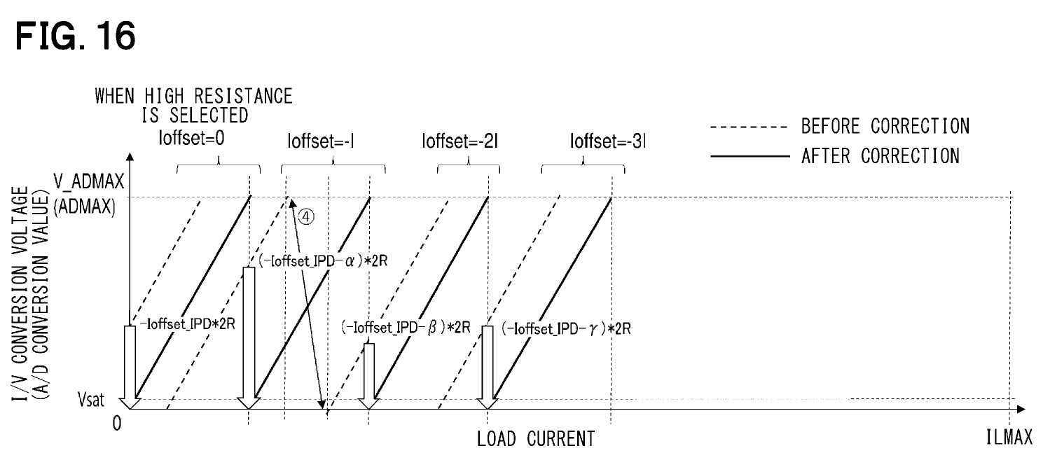

In addition, when controlling the current values of the sink-side current source unit 16 to -I, -2I, ... and so on, if variations such as -I+α, -2I+β, ... occur for each current source I value, the value of I_offset_trim in the sink-side current source 27 is dynamically controlled to -I_offset_IPD, -I_offset_IPD-α, -I_offset_IPD-β, ... and so forth, in order to compensate for such variations. As a result, as indicated by (4) in FIG. 16, it is possible to prevent the occurrence of regions where correct digital conversion cannot be achieved, thereby expanding the current range in which the load current IL can be detected with high resolution. It is also possible to adjust the sink-side current source 27 in cooperation with the sink-side current source unit 16, or to address this by setting finer adjustment steps for the sink-side current source unit 16.

### Sixth Embodiment

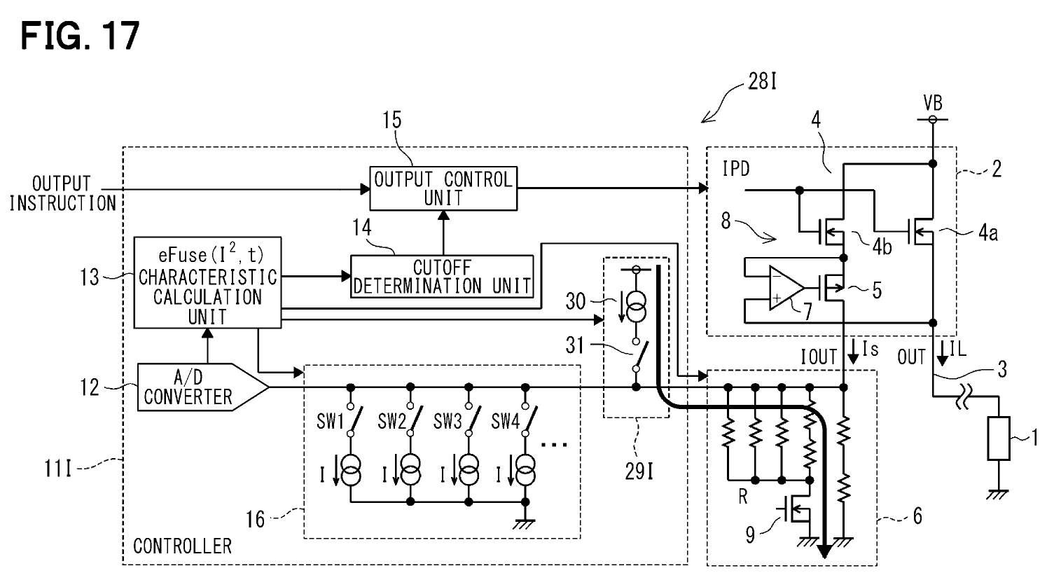

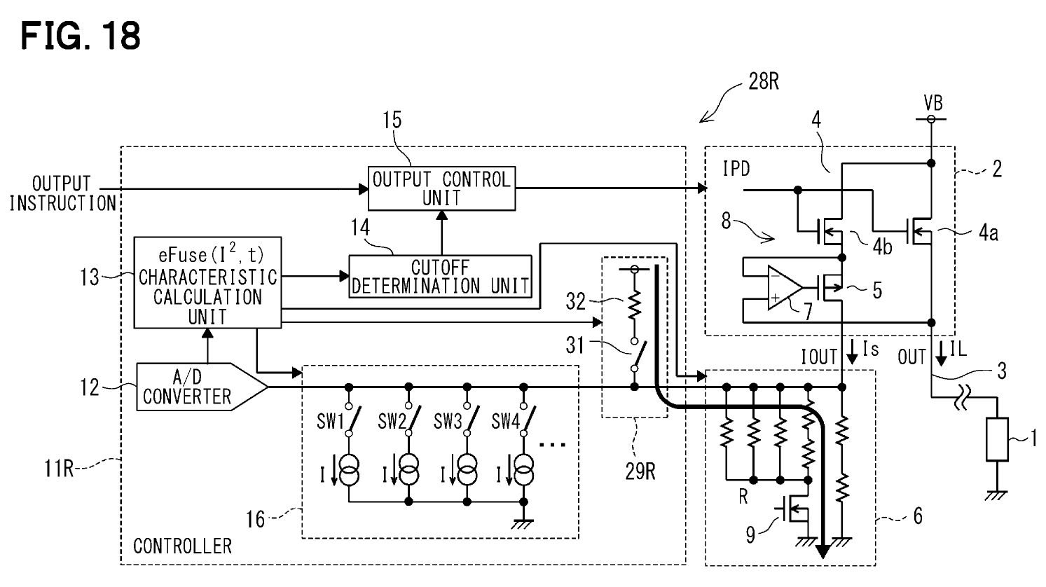

As shown in FIGS. 17 and 18, the power supply apparatuses 28I and 28R of the sixth embodiment are each provided with a source-side current supply source 29I and 29R, respectively, as a correction current supply source in controllers 11I and 11R. The source-side current supply source 29I includes a series connection of a current source 30 and a switch 31 connected between the power supply VB and ground, while the source-side current supply source 29R is configured by replacing the aforementioned current source 30 with a resistive element 32. The on/off control of the switch 31 is performed by the calculation unit 13 for the eFuse (I², t) characteristic.

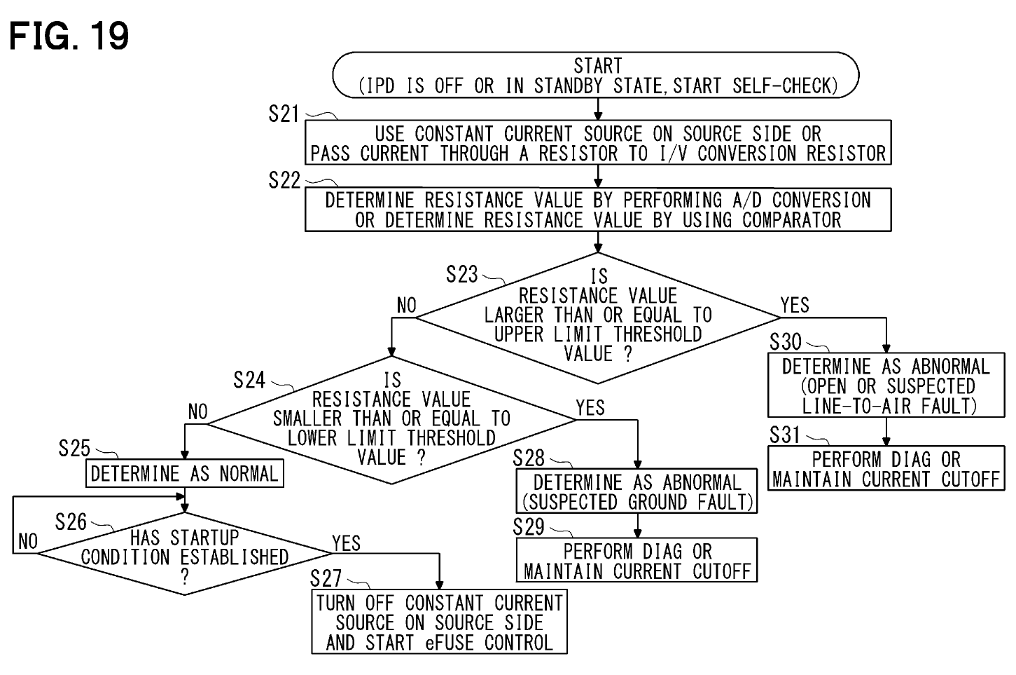

Next, the operation of the sixth embodiment will be described. As shown in FIG. 19, processing starts in a mode in which a self-check is performed, under the condition that the output control unit 15 has turned off the IPD 2 or is in standby mode. First, the switch 31 of the source-side current supply source 29I or 29R is turned on to supply current to the resistive element of the I/V conversion circuit 6 in S21. It may be preferable to initially set the resistance value of the I/V conversion circuit 6 to the low resistance side. Then, analog-to-digital conversion is performed by the A/D converter 12, and the resistance value that can be read from the conversion result is determined in S22.

If the determined resistance value is equal to or greater than the upper threshold (S23; Yes), there is a possibility that the connection of the I/V conversion circuit 6 is open or has a line-to-air fault, so it is determined as abnormal in S30. Then, for example, a command to execute diagnostics is sent to a higher-level control device or the off state of IPD 2 is maintained as is S31.

If the determined resistance value is equal to or less than the lower threshold (S24; Yes), there is a possibility that the connection of the I/V conversion circuit 6 is grounded, so it is determined as abnormal in S28. Then, processing similar to that in S31 is performed in S29. On the other hand, if the determined resistance value exceeds the lower threshold (S24; No), it is determined to be normal in S25. Then, for example, if the startup conditions are satisfied based on a command from a higher-level control device or the like (S26; Yes), IPD 2 is turned on and eFuse control is started in S27.

As described above, by turning IPD 2 off or the like and determining the resistance value when a source current is supplied to the I/V conversion circuit 6 via the source-side current supply source 29, it is possible to determine whether the connection of the I/V conversion circuit 6 is normal or abnormal. In addition, the resistance value of the I/V conversion circuit 6 is first set to a low resistance to perform the above determination, and if the determination result is normal, the resistance value is switched to a high resistance and the same determination is performed. By comparing the first A/D conversion result after switching to the high resistance with the A/D conversion result at the time of low resistance, it is possible to determine whether the former A/D conversion result is appropriate or not. If it is abnormal, it can be determined that only the connection on the high resistance side is abnormal.

### Seventh Embodiment

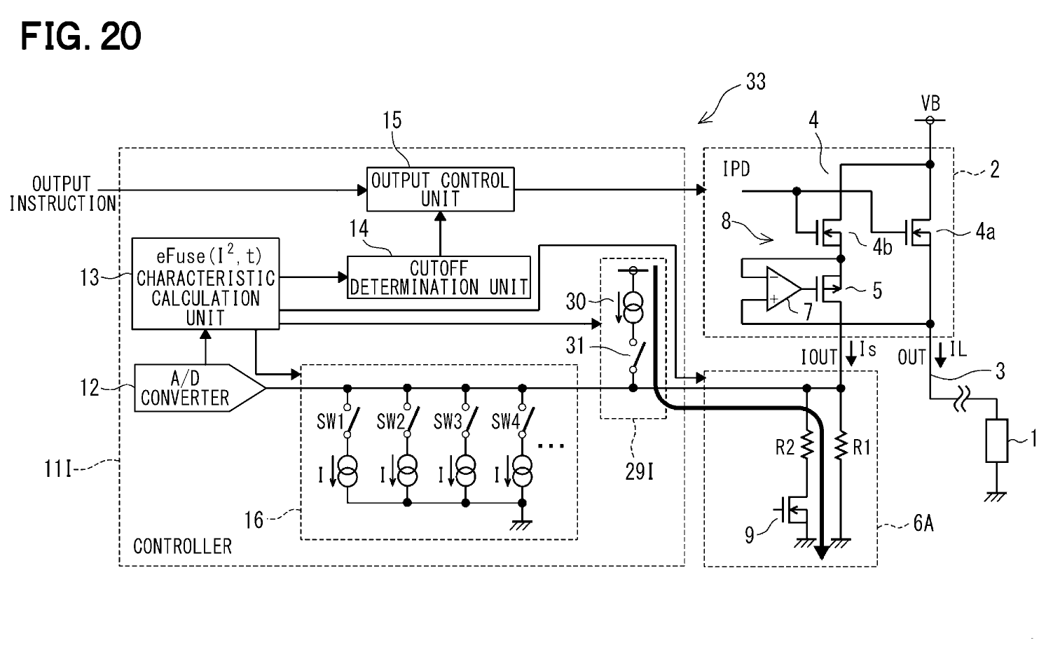

As shown in FIG. 20, the power supply apparatus 33 of the seventh embodiment is a combination of the controller 11I and the I/V conversion circuit 6A of the sixth embodiment. The I/V conversion circuit 6A is provided with a resistor R2, which is connected together with resistor R1 and FET 9 as a detection resistor, and is configured to switch the resistance value between R1 and the parallel resistance value of R1 and R2 (R1//R2). In the seventh embodiment, the type of IPD 2 connected to the I/V conversion circuit 6A is identified based on the resistance values of resistors R1 and R2.

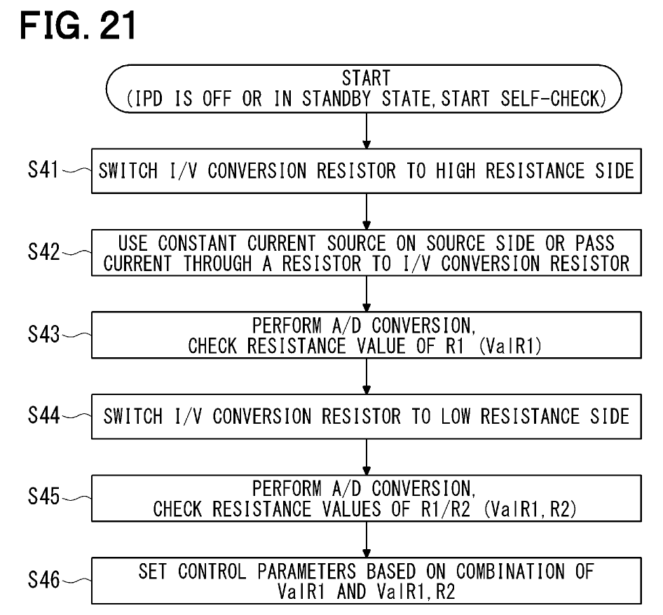

Next, the operation of the seventh embodiment will be described. As shown in FIG. 21, when processing starts in the self-check mode in the same state as in the sixth embodiment, the resistance value of the I/V conversion circuit 6A is switched to the high-resistance R1 in S41. The switch 31 of the source-side current supply source 29I is turned on to supply current to the resistor element of the I/V conversion circuit 6 in S42. Then, A/D conversion is performed by the A/D converter 12, and the conversion result is acquired as resistance value data ValR1 in S43.

Subsequently, the resistance value of the I/V conversion circuit 6A is switched to the low-resistance side, R1//R2 in S44, and A/D conversion is performed by the A/D converter 12, with the conversion result acquired as resistance value data ValR1_R2 in S45. Then, the control parameters are set based on the combination of the resistance value data ValR1 and ValR1_R2 in S46.

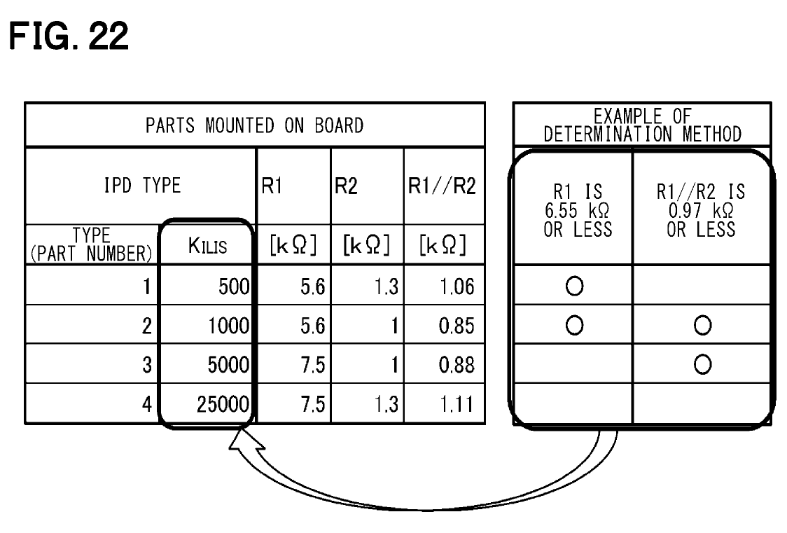

The controller 11I, for example, holds a data table for identifying the type of IPD2, as shown in FIG. 22. The drawing also shows an example of the determination method in S46; for example, if the resistance value R1 is 6.55 kΩ or less, the model numbers “1, 2” of IPD 2 are applicable. Additionally, if the resistance value R1//R2 is 0.97 kΩ or less, the model numbers “2, 3” of IPD2 are applicable. Based on these results, model number “2” is identified. Since the resistance ratio KILIS of model number “2” is “1000”, the parameter KILIS = 1000 is set for use in eFuse control. Other control parameters include, for example, the thickness of the wire harness, allowable current, the time constant of the cutoff characteristic, and the overcurrent threshold, among others.

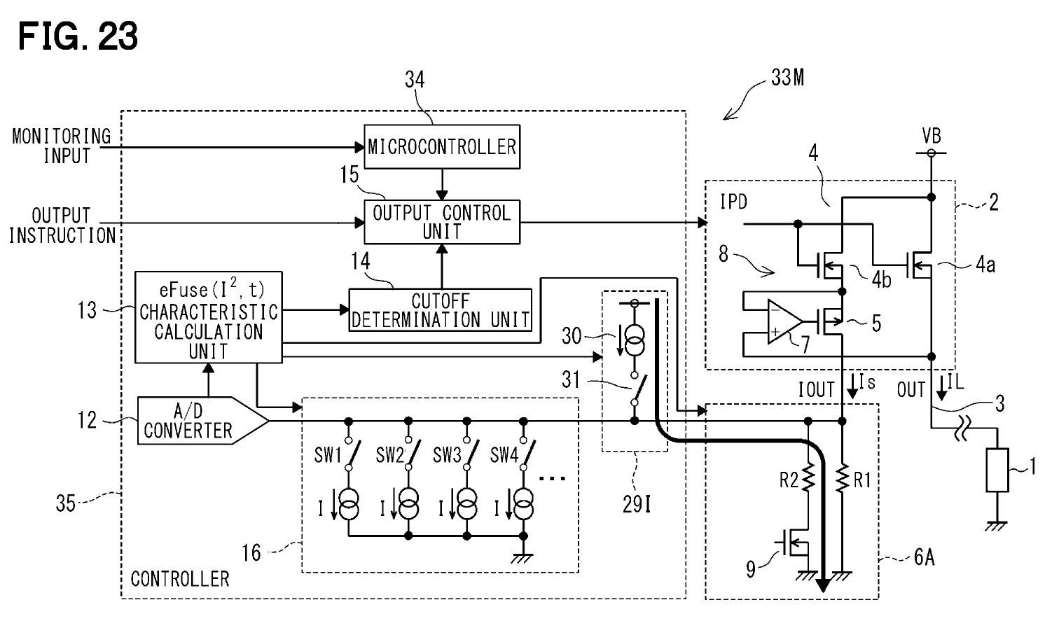

Additionally, the process shown in FIG. 21 may be executed at power-on, and the default behavior at startup (whether to turn on or off) may be switched according to the identified model number of IPD2. Furthermore, FIG. 23 shows a configuration using a controller 35, which includes a microcontroller 34 added to the controller 11I. In this case, the microcontroller 34 may be provided with a function to monitor the output control unit 15, and parameters such as the action to be taken when the microcontroller 34 detects an abnormality (such as forced on, forced off, or maintaining the previous state) may be set. Also, as shown in the sixth embodiment, the source-side current supply source 29R may be used in place of the source-side current supply source 29I.

### Eighth Embodiment

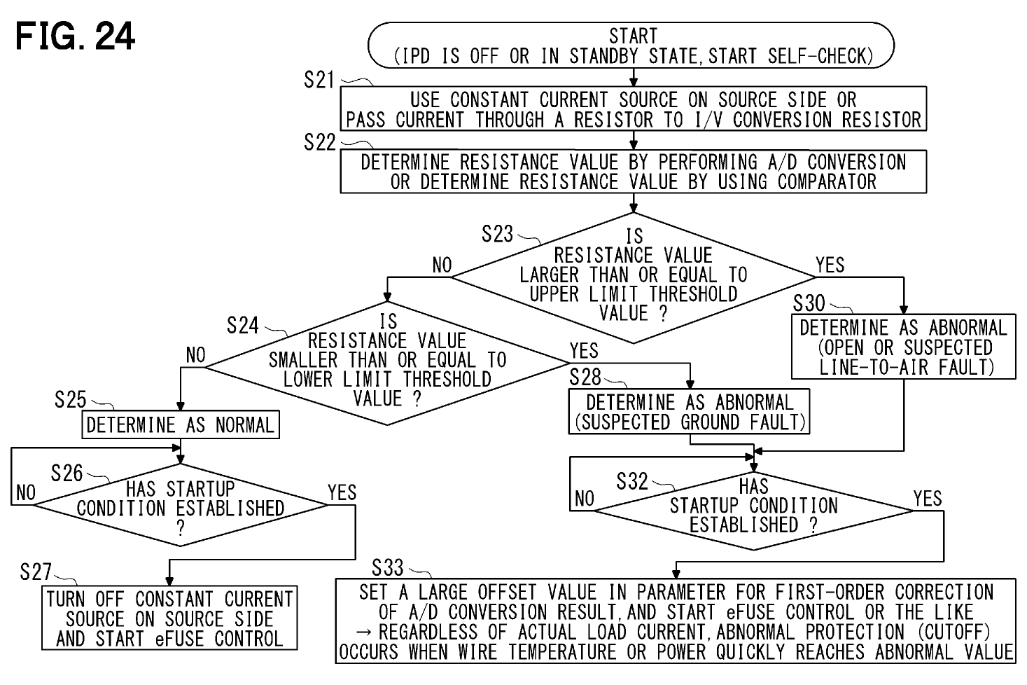

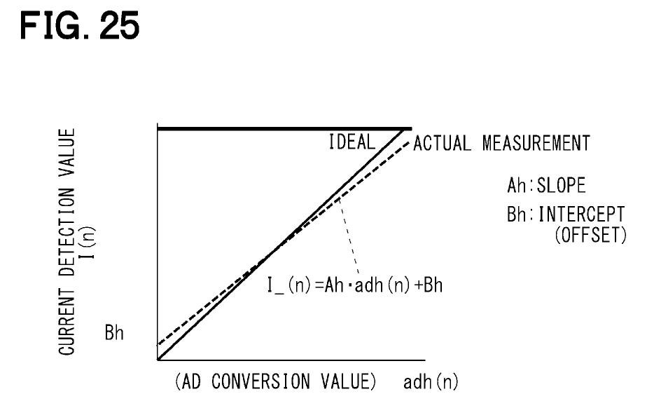

As shown in FIG. 24, the eighth embodiment determines the quality of the connection state of the I/V conversion circuit 6 in the same manner as the sixth embodiment. Then, after execution of S28 and S30, the determination of whether the startup condition is satisfied in S32 is conducted in the same way as in S26. If the startup condition is satisfied (Yes), for example, when a corrector performing correction on the A/D conversion result using a linear function, the intercept Bh, which is a parameter for the offset as shown in FIG. 25, is changed to a value larger than the value normally used in S33.

Thereafter, when energization is started by IPD 2, it is possible, based on the corrected value of the A/D conversion result, to make it appear as if a large current is flowing regardless of the actual load current IL. As a result, the eFuse control function or the power monitoring function activates the protection to cut off the current in a shorter time than usual, making it possible to safely protect the load 1. In other words, it can also be said that the eFuse control function or the power monitoring function activates the protection to cut off the current earlier than a predetermined time, or it can also be said that the period between the abnormal determination and the activation of the protection.

### Ninth Embodiment

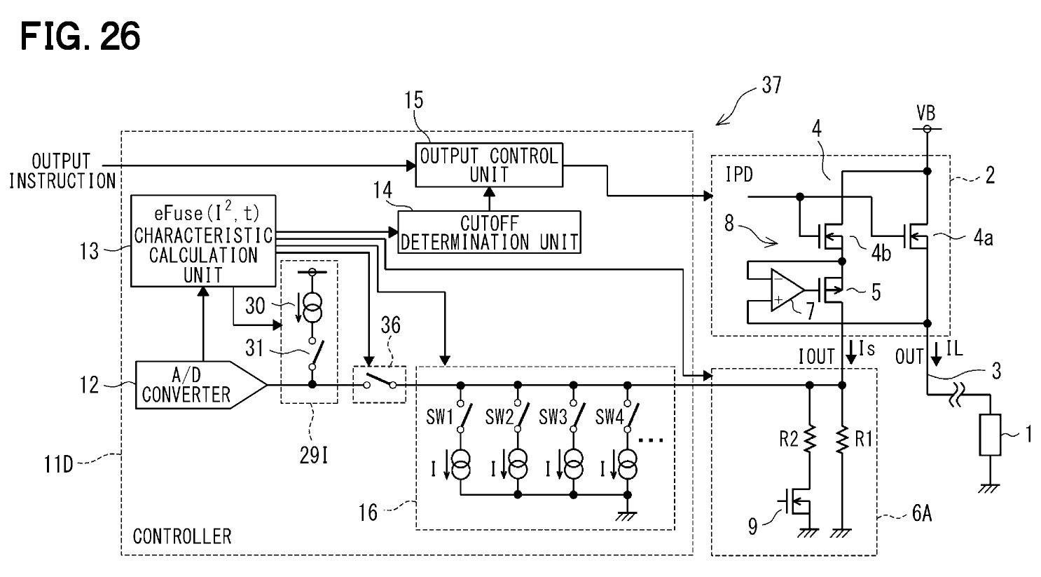

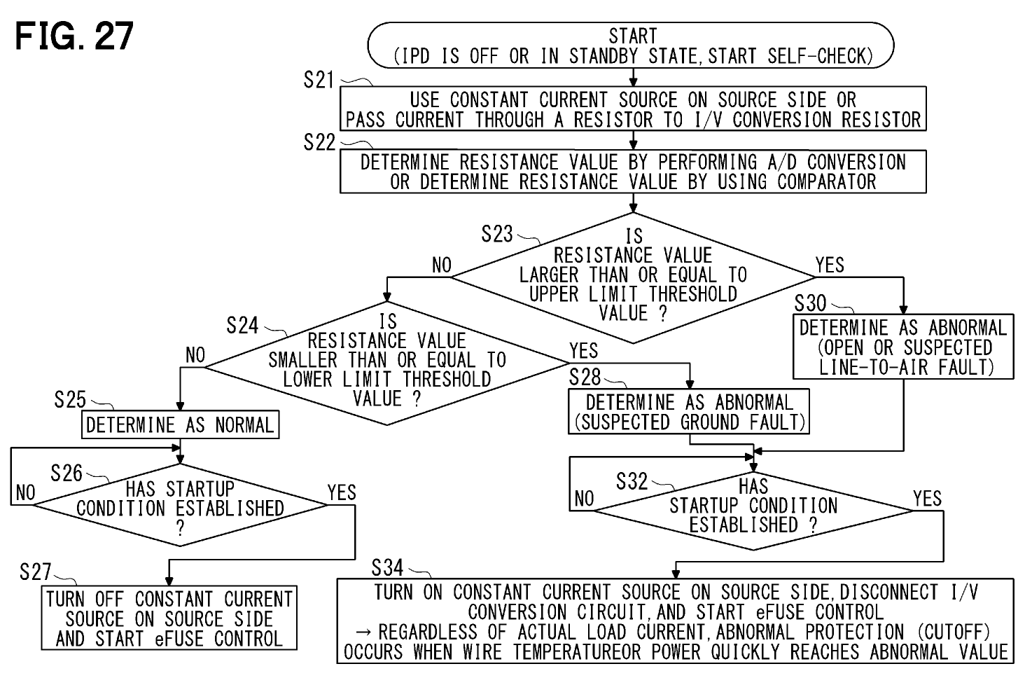

A ninth embodiment is a variation of the eighth embodiment. As shown in FIG. 26, a normally closed switch 36 is inserted between the input terminal of the A/D converter 12 and the sink-side current source unit 16, and the source-side current supply source 29I according to the sixth embodiment is connected to the common connection node between the input terminal and the switch 36. The on/off control of the switch 36 is performed by the eFuse (I², t) characteristic calculation unit 13. Then, as shown in FIG. 27, if the determination in S32 is “Yes,” switch 36 is turned off and the switch 31 of the source-side current supply source 29I is turned on in S34.

As a result, when energization by IPD 2 is subsequently started, it is made to be recognized, as in the eighth embodiment, that a large current is flowing regardless of the actual load current IL. As a result, protection that cuts off the current by means of the eFuse control function or the electric energy monitoring function operates in a short period of time, making it possible to safely protect the load 1.

### Other Embodiments

The change in resistance value in the I/V conversion circuit may be set to three or more stages. Furthermore, it is not always necessary to change the resistance value. The number of current sources provided in the sink-side current source unit may be “three or fewer” or “five or more.” It is also possible to integrate the A/D converter 12 and the eFuse (I², t) characteristic calculation unit 13 to configure a data converter that outputs conversion results corresponding to the quadratic characteristic of the current. For example, applicable embodiments may be appropriately combined and implemented, such as by applying the third embodiment to the second, and the fourth through ninth embodiments.

The present disclosure has been described in accordance with the embodiments, but it is understood that the present disclosure is not limited to these embodiments or structures. The present disclosure also encompasses various modifications and alterations within the scope of equivalents. In addition, various combinations and forms, as well as other combinations and forms that include only one element, more than one, or fewer than one of those elements, also fall within the scope and spirit of the present disclosure.

In the present disclosure or the claims, the phrase “at least one of a circuit and a processor” should be interpreted disjunctively (logical OR) and should not be interpreted as at least one circuit and at least one processor. Therefore, in the present disclosure or the claim, “at least one of a circuit and a processor” is configured to cause a controller to execute functions includes the case where only the circuit causes the controller to execute all the functions. Additionally, “at least one of a circuit and a processor is configured to cause a controller to execute functions” includes the case where only the processor causes the controller to execute all the functions. Furthermore, “at least one of a circuit and a processor is configured to cause a controller to execute functions” includes the case where the circuit causes the controller to execute some of the functions and the processor causes the controller to execute the remaining functions. In the last case, for instance, if the controller executes functions A to C, functions A and B may be implemented by the circuit, and the remaining function C may be implemented by the processor.

What is claimed is:

1. A power supply apparatus comprising:
a power device configured to supply current from a driving power supply to a load;
an I/V conversion circuit configured to convert the current into a voltage using a detection resistor through which the current passes;
a data converter configured to convert the voltage into a data value based on a predetermined characteristic;
a controller configured to execute a protection operation in which the power device is stopped from supplying the current to the load, on a condition that a calculated value derived from the data value exceeds a threshold value; and
sink-side current sources configured to superimpose, in multiple stages, offset values of current on the current passing through the detection resistor.

2. The power supply apparatus according to claim 1, wherein
the sink-side current sources are configured such that the voltage immediately before and immediately after a boundary between adjacent two of the offset values remain within an input range of the data converter.

3. The power supply apparatus according to claim 1, further comprising:
a storage configured to store, in advance, a difference value among data values associated with on and off states of the sink-side current sources, wherein
the controller is configured to, upon switching of the sink-side current sources, read from the storage the difference value corresponding to the switching, and subtract the difference value from the data value.

4. The power supply apparatus according to claim 1, wherein
the I/V conversion circuit is configured to selectively supply current to two or more detection resistors having different resistance values,
the data converter is configured to execute a first data conversion in a state in which the current is supplied to a detection resistor having a lowest resistance value among the two or more detection resistors, without superimposing the offset value of current on the current,
in accordance with a result of the first data conversion, the I/V conversion circuit is configured to select a detection resistor having a higher resistance value than the detection resistor used in the first data conversion, and the data converter is configured to execute a second data conversion in which the current is supplied to the selected detection resistor, and
the controller is configured to determine, based on the result of the first data conversion, an offset value to be superimposed on the current for the second data conversion.

5. The power supply apparatus according to claim 1, further comprising:
a current output circuit configured to output current proportional to load current flowing through the power device; and
a correction current supply source configured to correct offset current generated in the current output circuit.

6. The power supply apparatus according to claim 1, further comprising:
a source-side current supply source configured to supply current to the detection resistor during a state in which the power device is stopped from supplying the current to the load, wherein
the controller is configured to perform abnormal determination whether the detection resistor is abnormal, based on a result of data conversion by the data converter in conjunction with the current supplied by the source-side current supply source.

7. The power supply apparatus according to claim 6, further comprising:
a corrector configured to correct output data of the data converter, wherein
the controller is configured to set a correction parameter of the corrector to shorten a period from the abnormal determination to a start of the protection operation, based on a condition that the abnormal determination indicates that the detection resistor is abnormal.

8. The power supply apparatus according to claim 6, wherein
an input voltage of the data converter is set to exceed a normal input range of the data converter in response to a determination by the controller that the detection resistor is abnormal.

9. The power supply apparatus according to claim 1, further comprising:
a source-side current supply source configured to supply current to the detection resistor during a state in which the power device is stopped from supplying the current to the load, wherein
the controller is configured to:
determine a type of the power device connected based on a result of data conversion by the data converter performed in conjunction with the current supplied by the source-side current supply source; and
set a control parameter according to the determined type.
